(19) United States
(12) Patent Application Publication
(10) Pub. No.: US 2008/0057723 A1
(43) Pub. Date: Mar. 6, 2008

(54) IMAGE SENSOR AND METHOD FOR MANUFACTURING THE SAME

(76) Inventor: Kyung-Min Park, Incheon (KR)

Correspondence Address: SHERR & NOURSE, PLLC, 620 HERNDON PARKWAY, SUITE 200, HERNDON, VA, 20170, US

(21) Appl. No.: 11/846,943

(22) Filed: Aug. 29, 2007

(30) Foreign Application Priority Data
Aug. 31, 2006 (KR) 10-2006-0083913

(51) Int. Cl. H01L 21/311

(52) U.S. Cl. 438/703; 257/E21.249

(57) ABSTRACT

A method for manufacturing an image sensor according to embodiments includes forming a transistor over a substrate. A protective layer including boron (B) may be formed, covering the transistor formed over the substrate. The protective layer including the boron may be annealed to move foreign substances including the boron to the surface of the protective layer. The surface of the protective layer including the foreign material may be removed. An oxide protective layer may be formed over the protective layer including the boron where the foreign substance is removed.

The present application claims priority under 35 U.S.C. 119 to Korean Patent Application No. 10-2006-0083913, filed Aug. 31, 2006, which is hereby incorporated by reference in its entirety.

### BACKGROUND

An image sensor, which is a semiconductor device converting an optical image into an electrical signal, may be classified as a charge coupled device (CCD) or a complementary metal oxide silicon (CMOS) image sensor (CIS). An image sensor may have a photo diode and a MOS transistor in a unit pixel to sequentially detect electrical signals of each unit pixel, thereby forming an image.

FIG. 1 is a photograph showing a fault in an image sensor. The manufacturing process may use a boron phosphor silicate glass layer (BSPG) as an interlayer dielectric layer (PMD) material. In a CIS device, an oxide film may be ripped out or otherwise damaged in a subsequent annealing process. It may be detached due to an interface adhesion problem between the BPSG material and a subsequent oxide film. A detached oxide film may fall within the pixel region of a CIS, causing the device characteristics to be degraded.

### SUMMARY

Embodiments relate to a method for manufacturing an image sensor improving the interface adhesion characteristics between a PMD material and subsequent oxide film material, making it possible to reduce defects. A method for manufacturing an image sensor according to embodiments includes forming a transistor over a substrate. A protective layer including boron (B) may be formed, covering the transistor formed over the substrate. The protective layer including the boron may be annealed to move foreign substances including the boron to the surface of the protective layer. The surface of the protective layer including the foreign material may be removed. An oxide protective layer may be formed over the protective layer including the boron where the foreign substance is removed.

A method for manufacturing an image sensor according to embodiments may also include forming a transistor over a substrate. A protective layer including phosphorus (P) may be formed, covering the transistor. The protective layer including the phosphorus may be annealed to move foreign substances including the phosphorus to the surface of the protective layer. The surface of the protective layer including the foreign material may be removed. An oxide protective layer may be formed over the protective layer.

### DRAWINGS

FIG. 1 is a photograph showing a problem of an image sensor according to the related art.

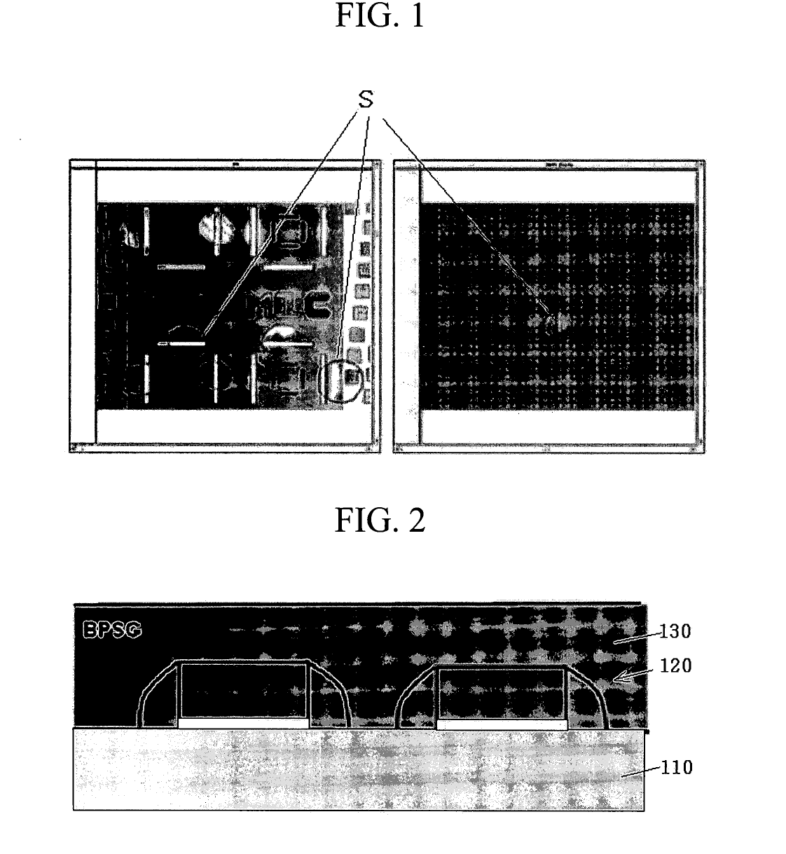

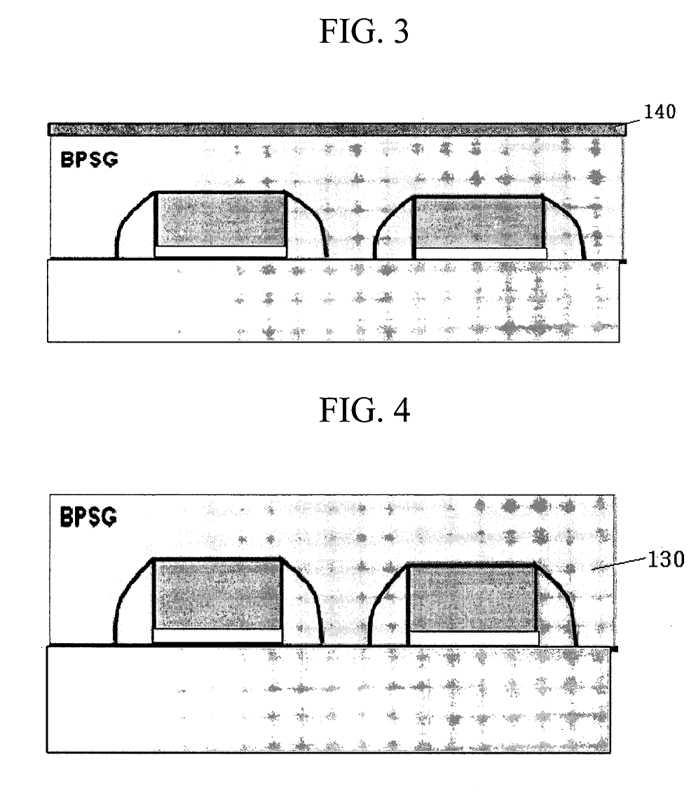

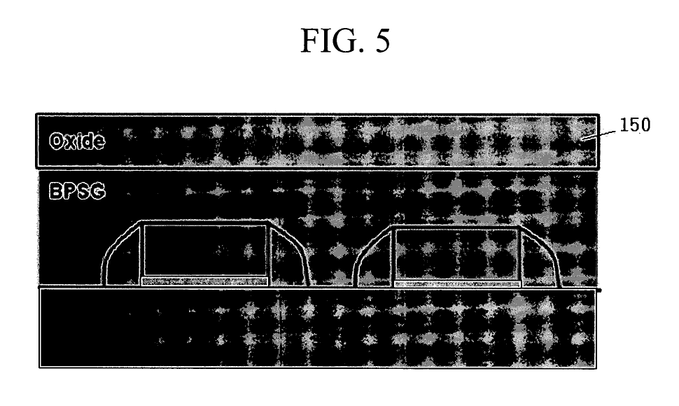

Example FIGS. 2 to 5 are cross-sectional views showing a method for manufacturing an image sensor according to embodiments.

### DESCRIPTION

Example FIGS. 2 to 5 are cross-sectional views showing a method for manufacturing an image sensor according to embodiments. A method for manufacturing the image sensor according to embodiments may use a BPSG protective layer, but protective layers which can be used with embodiments are not limited thereto. Besides the BPSG protective layer, for example embodiments can use a BSG or PSG protective layer.

A protective layer including boron (B) may be formed, covering the transistor formed over the substrate. The protective layer including the boron may be annealed to move foreign substances including the boron to the surface of the protective layer. The surface of the protective layer including the foreign material may be removed. An oxide protective layer may be formed over the protective layer including the boron where the foreign substance is removed.

As shown in example FIG. 2, a transistor 120 is formed over a substrate 110. The transistor 120 may include a gate insulating layer and a gate over the substrate 110. Silicide spacers may be formed over both sides of the gate.

Thereafter, a protective layer including boron (B) may be formed to cover the transistor 120. The protective layer including the boron (B) may be a boron phosphor silicate glass layer (BPSG) protective layer or a boron silicate glass (BSG) protective layer. Embodiments below describe a BSPG protective layer 130, but they are not limited thereto.

Next, as shown in example FIG. 3, the BPSG protective layer 130 is annealed to move foreign substances within the BPSG protective layer 130 to the surface thereof (140).

At this time, the annealing process on the BPSG protective layer 130 can be performed at a temperature of 100 to 300° C. In other words, the process is a process after the transistor 120 is formed and does not exceed 300° C. not to apply a thermal attack on the transistor. Also, it has a problem not to apply thermal energy sufficient for moving the foreign substance at a temperature below 100° C.

The annealing process on the BPSG protective layer 130 is performed at a temperature of 100 to 300° C. for 10 to 60 minutes. For example, when the annealing process is performed around 300° C. for about 10 minutes, or is performed around 100° C. for about 60 minutes, the thermal energy is sufficient for moving foreign substances 140 to the surface.

In embodiments, after the BPSG protective layer 130 is deposited, boron (B) and phosphorus (P) are moved to the surface of the BPSG through the annealing process (140). The boron (B) and the phosphorus (P), which are foreign substances, are receive thermal energy from the annealing process and move to the surface of the BPSG, where their energy state is thermodynamically high, to lower the entire energy.

As shown in example FIG. 4, the surface of the BPSG protective layer 140 including the foreign substance may be removed. The surface of the BPSG protective layer 140 may be removed by plasma etching, for example. N₂O plasma having a density of 3×10¹⁰ ion/in² to 3×10¹⁵ ion/in² may be applied for 5 to 300 seconds to remove the surface of the BPSG protective layer 140. A mixture of N₂O and NH₃ plasma, for example, may also be used at the same density and duration.

As shown in example FIG. 5, an oxide protective layer 130 may be formed over the BPSG protective layer 130 where foreign substances were removed. Since the boron (B) and the phosphorus (P), which are foreign substances causing problems with the adhesion of the oxide film, are removed, the adhesion of the oxide protective layer 130 and the BPSG protective layer 130 is excellent.

The characteristics of the interface adhesion, then, between the BPSG protective layer 130, which is a PMD material of the image sensor, and the oxide film 150 material may be maximized by this process. Circuit defects and faults may be reduced. Performance of the image sensor and the yield thereof may be maximized.

A method for manufacturing an image sensor according to embodiments may also include forming a transistor over a substrate. A protective layer including phosphorus (P) may be formed, covering the transistor. The protective layer including the phosphorus may be annealed to move foreign substances including the phosphorus to the surface of the protective layer. The surface of the protective layer including the foreign material may be removed. An oxide protective layer may be formed over the protective layer.

In a method for manufacturing the image sensor according to embodiments, the protective layer including phosphorus (P) may be a BPSG protective layer or a phosphor silicate glass (PSG) protective layer.

Embodiments may relate to a protective layer including the phosphorus (P), rather than Boron (B), while generally following the laid out for Boron.

In embodiments, since phosphorus (P), which is a foreign substance causing problems in the adhesion with the oxide film, may be removed from the protective layer, the adhesion of the protective layer including the phosphorus (P) and a subsequent oxide protective layer may be maximized. The characteristics of the interface adhesion between the protective layer including phosphorus (P), which is a PMD material of the image sensor, and the oxide film material may be maximized by this process. Circuit defects and faults may be reduced.

As described above, with the method for manufacturing the image sensor according to the embodiment improves the interface adhesion between the BPSG, the BSG, or the PSG and a subsequent oxide film. Circuit defects and faults may be reduced. Performance of the image sensor and the yield thereof may be maximized.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a transistor over a substrate;
forming a first protective layer including boron covering the transistor;
annealing the first protective layer to move foreign substances to a surface of the first protective layer;
removing the surface of the first protective layer including the foreign substances; and
forming a second protective layer over the surface of first protective layer.

2. The method of claim 1, wherein the first protective layer including boron is a boron phosphor silicate glass.

3. The method of claim 1, wherein the first protective layer including boron is a boron silicate glass.

4. The method of claim 1, wherein the annealing process on the first protective layer including boron is performed at a temperature between approximately 100 and 300° C.

5. The method of claim 4, wherein the annealing process on the first protective layer including boron is performed for a duration between approximately 10 and 60 minutes.

6. The method of claim 1, wherein removing the surface of the first protective layer, including the foreign substances, is performed with N₂O plasma having a density of approximately 3×10¹⁰ ion/in² to 3×10¹⁵ ion/in².

7. The method of claim 1, wherein removing the surface of the protective layer, including the foreign substances, is performed with N₂O and NH₃ plasma having a density of approximately 3×10¹⁰ ion/in² to 3×10¹⁵ ion/in².

8. The method of claim 1, wherein the second protective layer comprises an oxide.

9. A method comprising:
forming a transistor over a substrate;
forming a first protective layer including phosphorus covering the transistor;
annealing the first protective layer to move foreign substances to a surface of the first protective layer;
removing the surface of the first protective layer including the foreign substances; and
forming a second protective layer over the surface of first protective layer.

10. The method of claim 9, wherein the first protective layer including the phosphorus is a boron phosphor silicate glass.

11. The method of claim 9, wherein the first protective layer including the phosphorus is a phosphor silicate glass.

12. The method of claim 9, wherein the annealing process on the first protective layer including phosphorus is performed at a temperature of approximately 100 to 300° C.

13. The method of claim 12, wherein the annealing process on the protective layer including the phosphorus is performed for approximately 10 to 60 minutes.

14. The method of claim 9, wherein removing the surface of the first protective layer including the foreign substances is performed with N₂O plasma having a density of approximately 3×10¹⁰ ion/in² to 3×10¹⁵ ion/in² for approximately 5 to 300 seconds.

15. The method of claim 9, wherein removing the surface of the protective layer including the foreign substances is performed with N₂O and NH₃ plasma having a density of approximately 3×10¹⁰ ion/in² to 3×10¹⁵ ion/in² for approximately 5 to 300 seconds.

16. The method of claim 9, wherein the second protective layer comprises an oxide.
